(19) United States
(12) Patent Application Publication
(10) Pub. No.: US 2017/0016447 A1
(43) Pub. Date: Jan. 19, 2017

(54) METHOD AND APPARATUS IN CONNECTION WITH A SCREW COMPRESSOR

(71) Applicant: ABB Technology OY, Helsinki (FI)

(72) Inventors: Antti Kosonen, Lappeenranta (FI); Jero Ahola, Lappeenranta (FI)

(21) Appl. No.: 15/210,679

(22) Filed: Jul. 14, 2016

(30) Foreign Application Priority Data
Jul. 15, 2015 (EP) 15176847.0

(51) Int. Cl. F04C 28/28; G01R 21/133; F04C 29/00; F04C 18/16; F04C 28/08

(52) U.S. Cl. CPC F04C 28/28; F04C 18/16; F04C 28/08; F04C 29/0085; G01R 21/133; F04C 2270/80

(57) ABSTRACT

the screw compressor with a variable rotational speed of the screw compressor, the rotational speed of the screw compressor having a speed profile in which the rotational speed is changed stepwise such that between stepwise changes the rotational speed of the screw compressor is kept substantially constant for a time period, repeating the speed profile until the pressure of the pressure vessel reaches a set pressure value, determining pressure of the pressure vessel, power consumption of the screw compressor drive and mass flow rate during the pressurising when the rotational speed of the screw compressor is kept substantially constant, calculating energy efficiency of the screw compressor drive as a function of pressure of the pressure vessel and rotational speed of the screw compressor on the on the basis of the determined pressure of the pressure vessel and power consumption of the screw compressor drive.

### FIELD OF THE INVENTION

The present invention relates to screw compressors, and particularly to screw compressors driven with a frequency converter.

### BACKGROUND OF THE INVENTION

Screw compressors are widely used compressor types for producing pressurized gas for multiple of purposes. One of the uses of screw compressors is in pressurised air systems for generating pressurised air to a vessel or similar pressure tank from which the pressurised air is used through hoses or pipes, for example. In such a system, the screw compressor is operated to provide a desired pressure to the vessel and keep the vessel pressurized during the use of the pressurized air.

Screw compressors are rotated by an electric motor for generating the pressure. Further, frequency converters are often employed to drive the electric motor in a controlled and efficient manner. In order to control the system efficiently with a frequency converter the system should be identified with respect to its different operation points and characteristic power consumption in these operation points.

The power consumptions in different operation points can be gathered by excessive test procedures in which consumption data is gathered in each of the operation points. However, such operation takes a long time. Further, the properties of the screw compressor system may change, and therefore the procedures for determining the most efficient operation points should be repeated regularly to obtain reliable results.

### BRIEF DESCRIPTION OF THE INVENTION

An object of the present invention is to provide a method and an apparatus for implementing the method so as to solve the above problem. The objects of the invention are achieved by a method and an apparatus which are characterized by what is stated in the independent claims. The preferred embodiments of the invention are disclosed in the dependent claims.

The invention is based on the idea of filling the pressure vessel of the screw compressor system in such a manner that during the filling or pressurizing the vessel the efficiency or power consumption of the system can be determined in desired operating points. Further, an energy consumption map may be generated on the basis of a single filling of the vessel. Such map may be used for determining the optimal rotation speed reference for the frequency converter depending on the pressure of the vessel.

An advantage of the invention is that already after the filling of the pressure vessel the optimal rotation speeds can be determined without any external measurement instruments using only the internal measurements of the frequency converter.

### BRIEF DESCRIPTION OF THE DRAWINGS

In the following the invention will be described in greater detail by means of preferred embodiments with reference to the attached drawings, in which

FIG. 1 shows a speed profile used in an embodiment of the invention;

FIG. 2 shows mass flow profile obtained with speed profile of FIG. 1;

FIG. 3 shows pressure ratio as a function of rotational speed obtained with the speed profile of FIG. 1;

FIG. 4 shows plots of energy consumption as a function of pressure ratio;

FIG. 5 shows plots of energy consumption as a function rotational speed; and

FIG. 6 shows path of optimal rotation speed as a function of pressure ratio.

### DETAILED DESCRIPTION OF THE INVENTION

In the present invention a screw compressor drive, comprising a screw compressor and a frequency converter, is driven with a frequency converter. As known, a frequency converter can drive an electric motor with a variable rotation speed. In the system associated with the invention, the output of a frequency converter is connected to an electric motor, which rotates the screw compressor for producing pressurized gas.

Frequency converters include typically processors having calculation capacity and internal measurements. The measurements relate, for example, to rotational speed, torque and power. These measurements can be used in the processor of the device for further calculations.

In the present invention, a pressure vessel of a screw compressor driven with a frequency converter is filled or pressurised. According to an embodiment of the invention, the pressurising is carried out using a specific speed profile in which speed is changed in a timed manner. In the speed profile the speed is changed stepwise and kept substantially constant for a time interval. The same speed profile is repeated until the pressure vessel of the system is pressurized to a set level. The speed profile is kept constant for a specified time interval so that the system stabilizes for accurate measurements. A suitable value for the constant speed operation is in the range of 5 to 25 seconds depending on the properties of the system. The mentioned properties include possible time delays in measurement and the settling time of the system.

According to an embodiment of the invention, the speed profile is repeated at least three times during the filling of the pressure vessel. The repeating of the speed profile is carried out with substantially same changes in rotational speed and keeping the rotational speed substantially constant at the same levels each time the profile is repeated.

FIG. 1 shows an example of a speed profile used in an embodiment. First, the speed is increased to 2000 rpm for building initial pressure to the pressure vessel. The speed is then decreased to approximately 700 rpm and from which the stepwise changes are started at approximate time instant 800 s. In the example of FIG. 1, the speed is increased with steps of 300 rpm and kept substantially constant for a period of 10 seconds.

FIG. 2 shows the mass flow rate obtained with the speed profile of FIG. 1 and FIG. 3 shows pressure ratio of the vessel as a function of motor speed obtained with the speed profile of FIG. 1. The pressure ratio is the ratio of pressure of the vessel and of the ambient. When the ambient pressure is at a normal level, then the pressure ratio corresponds directly to the pressure of the vessel (i.e. ambient pressure is one bar). From FIG. 2 it can be seen, that the mass flow rate is linear with respect to rotational speed in a screw compressor. Thus when the mass flow rate of a single rotational speed of the screw compressor is known, the mass flow rates of any rotational speed can be directly calculated. Typically a mass flow rate with nominal rotational speed is known.

It is seen from FIG. 3 that the stepwise changes of the rotational speed cause a stepwise change in the pressure. Further, when the speed profile is repeated, the vessel is pressurised with the same rotational speeds with different pressures.

According to the invention, the power consumption of the screw compressor system is determined during the pressurising of the pressure vessel. Preferably the power consumption of the whole system is determined so as to find the optimal rotational speed as a function of the pressure of the vessel. The output power of the frequency converter can be calculated on the basis of the output voltage and output current of the frequency converter in a known manner, both of which are known readily at the frequency converter. Therefore, the output power of the frequency converter P_{fc,output} can be calculated in the known manner as a product between the output current and output voltage taking also into account the power factor. The losses of the frequency converter P_{fc,loss} can be estimated using an equation

$${P}_{fc , loss} = ( 0.35 + 0.1 \frac{f}{{f}_{n}} + 0.55 \frac{T}{{T}_{n}} ) {P}_{fc , loss , nom}$$

in which f is the output frequency of the frequency converter, fₙ is the nominal frequency of the frequency converter, T is the motor torque, Tₙ is the nominal motor torque, and P_{fc,loss,nom} is the losses of the frequency converter in the nominal point. The torque is readily available in the control system of the frequency converter similarly as the rotational speed.

The input power Pᵢₙ to the frequency converter can be calculated as a sum of the losses of the frequency converter and output power of the frequency converter.

The equation given above is an example of a possible approximation of the losses of the frequency converter. The losses can be calculated or determined using other possible procedures. It is even possible to directly measure the input power to the frequency converter using the internal measurements of a frequency converter.

The input power or power consumption is determined each time after the stepwise change in the speed profile. The pressure of the screw compressor is also known in the frequency converter. The frequency converter may even be pressure controlled such that the speed profile is obtained by changing pressure reference to the system.

It can be seen from the example of FIG. 3 that when operated according to the invention, the screw compressor operates at least three different pressure ratios with the same rotational speed. This means that with the same rotational speed at least three energy consumption values are obtained relating to different pressure ratios. As mentioned, the rotational speed is changed in the procedure, and therefore power consumption measurements are obtained with multiple rotational speeds each with a multiple of pressure ratios. If the pressure ratio varies slightly during constant speed operation of the frequency converter, then an average value of the pressure ratios can be calculated during the constant speed operation. The average value of the pressure ratio is then used as representing the pressure ratio in that constant speed operation. Similarly, if the power consumption varies during the constant speed operation, an average of the power consumption may be calculated and used as a value representing power consumption.

The determined power consumption as such does not indicate the efficiency relating to operation of the compressor. The energy efficiency of the compressor drive can be calculated as

$${E}_{s} = \frac{{P}_{i n}}{{q}_{m} \cdot 3600} ,$$

in which Pᵢₙ is the input power to the compressor drive (i.e. input power of the frequency converter) and qₘ is the mass flow rate (kg/s). The above equation tells how much energy has to be consumed to get mass flow rate of pressurised air and the obtained unit of efficiency is kWh/kg.

The obtained energy consumption data is stored and used for calculating efficiency or energy consumption in one or more operating points. One possibility of using the gathered data is to build an optimal rotational speed curve as a function of a pressure ratio. From such a curve the optimal rotational speed of the frequency converter can be read depending on the pressure ratio. One possible way of forming such a curve is presented below.

On the basis of FIG. 3 and the calculated energy consumption, the energy efficiency Eₛ can be plotted as a function of pressure ratio pr with fixed rotational speeds n. That is, for rotational speeds in which the power consumption was measured, the energy efficiency is plotted as a function of pressure ratio. Examples of such plots are shown in FIG. 4 for rotational speeds of n=1000 and n=2000.

The specific samples in the plots of FIG. 4 are shown as dots. Further, on the basis of the same values, a second order polynomial fitting curve formed and it is presented also in FIG. 4. The fitting curve approximates the behaviour of the energy consumption when the pressure ratio changes. In other words, at least second order polynomial fitting curves for pressure ratio and specific energy consumption for the selected rotational speeds are defined.

Next the power consumption is plotted as a function of rotational speed with constant pressure ratios pr. That is to say that for different pressure ratios the energy consumption is plotted as a function of rotational speed of the motor. Examples of such plots are shown in FIG. 5 for pressure ratios 2 and 3. The values (dots) of energy efficiency in FIG. 5 for specific pressure ratios are read from the curves of FIG. 4, i.e. for plot of pressure ratio=2, a value with a pressure ratio of 2, is read from the chart n=1000 and from the chart n=2000. Thus a vector for pressure ratios is formed, and at least second order polynomial fitting curves are calculated for rotational speed and specific energy consumption or efficiency for fixed pressure ratios.

FIG. 5 further shows a second polynomial fitting made to the presented values. In FIG. 5 only two data points are shown and the fitting curve is a straight line. However, with more data points a second order curve fitting produces a curve that approximates the change of energy efficiency with rotational speed.

From the values presented in plots of FIG. 5 and from the fitting curve, the optimal rotational speed of the motor can be read when the pressure ratio is known. The plots of FIG. 5 can be combined in a matrix to present the energy efficiencies as a function of rotational speed and pressure ratio. The rotation speeds can be selected from the curves and they do not have to be the same as used in the initial measurement. Further, the lowest energy consumptions, i.e. best efficiencies with different pressure rations can be collected to a single chart which presents optimal rotational speed curves as a function of pressure ratio. Such values are presented in FIG. 6 with a polynomial fitting. When such a curve is followed based on the pressure ratio, the energy consumption of the system is minimized.

In the above, the gathered data is utilized in different plots. The plots and drawings are used only to visualize the procedure that may be followed to obtain optimum operation points. It is clear that the calculations, such as curve fittings, are done without need for plotting the information.

Further, when the optimum operating rotational speed is needed only in few pressure ratios, the calculation may be simplified from the above described procedure. The curve fittings presented in the above example can also be replaced with another approximation. Such another approximation can be, for example, simple interpolation between two consecutive measurement points or higher order polynomial fittings.

The examples of FIGS. 4 and 5 show limited number of data points. It is however clear that when the energy efficiency is determined throughout the rotational speed range as illustrated in FIGS. 1 to 3, more data points are gathered.

When the procedure according to the invention is repeated, possible wear or malfunction of the system can be detected if the optimum points deviate from each other. That is, if the repeated measurement gives results that show changes in the optimum frequency with one or multiple of pressure ratios, it can be concluded that some properties of the system has changed. For example, oil-free compressor systems are prone to mechanical wear, and this wear can be detected by monitoring the changes in the optimum operating points.

The invention may be implemented into existing systems. Existing devices comprise a processor and a memory that may be utilized to implement the functionality of the embodiments of the invention. Hence all changes and configurations needed for implementing the embodiments of the invention, may be performed by software routines, which in turn may be implemented as added or updated software routines. If the functionality of the invention is implemented by software, the software may be provided as a computer program product comprising a computer program code which, when run on a computer, causes the computer, or similar equipment, to perform the functionality of the invention as described above. The computer program code may be stored on a computer readable medium, such as a suitable memory means, e.g. a flash memory or on a disc memory, from which it is readable to the unit or units executing the program code. In addition, the program code may be loaded to the unit or units executing the program code through a suitable data network and it may replace or update a possibly existing program code.

It will be obvious to a person skilled in the art that, as the technology advances, the inventive concept can be implemented in various ways. The invention and its embodiments are not limited to the examples described above but may vary within the scope of the claims.

1. A method of determining operation characteristics of a screw compressor drive comprising a screw compressor driven with a frequency converter, wherein the method comprises
pressurising a pressure vessel of the screw compressor with a variable rotational speed of the screw compressor, the rotational speed of the screw compressor having a speed profile in which the rotational speed is changed stepwise such that between stepwise changes the rotational speed of the screw compressor is kept substantially constant for a time period,
repeating the speed profile until the pressure of the pressure vessel reaches a set pressure value,
determining pressure of the pressure vessel, power consumption of the screw compressor drive and mass flow rate during the pressurising when the rotational speed of the screw compressor is kept substantially constant,
calculating energy efficiency of the screw compressor drive as a function of pressure of the pressure vessel and rotational speed of the screw compressor on the on the basis of the determined pressure of the pressure vessel and power consumption of the screw compressor drive.

2. Method according to claim 1, wherein the method comprises
selecting optimal rotational speed for the frequency converter as a function of pressure of the pressure vessel.

3. Method according to claim 1, wherein the calculating energy efficiency comprises
selecting multiple of rotational speeds,
calculating at least a second order polynomial fitting curves for pressure ratio and energy efficiency for selected rotational speeds,
selecting multiple of pressure ratios,
calculating at least a second order polynomial fitting curves for rotational speed and energy efficiency for selected pressure ratios, and
for each of the selected pressure ratios, determining a rotational speed having the best energy efficiency from the calculated polynomial fitting curves for rotational speed and energy efficiency.

4. Method according to claim 3, wherein after determining the rotational speed having the best energy efficiency, the rotational speed used in control of the frequency converter is selected based on the pressure ratio.

5. Method according to claim 1, wherein the power consumption of the screw compressor drive is estimated based on output power of the frequency converter and internal losses of the frequency converter.

6. Method according to claim 1, wherein the internal losses of the frequency converter are calculated on the basis of the torque of the motor, the nominal torque of the motor, output frequency of the frequency converter, nominal output frequency of the frequency converter and the losses of the frequency converter in a nominal operating point.

7. A screw compressor drive comprising a screw compressor driven with a frequency converter, wherein the system comprises
means for pressurising a pressure vessel of the screw compressor with a variable rotational speed of the screw compressor, the rotational speed of the screw compressor having a speed profile in which the rotational speed is changed stepwise such that between stepwise changes the rotational speed of the screw compressor is kept substantially constant for a time period,
means for repeating the speed profile until the pressure of the pressure vessel reaches a set pressure value,
means for determining pressure of the pressure vessel, power consumption of the screw compressor drive and mass flow rate during the pressurising when the rotational speed of the screw compressor is kept substantially constant,
means for calculating energy efficiency of the screw compressor drive as a function of pressure of the pressure vessel and rotational speed of the screw compressor on the on the basis of the determined pressure of the pressure vessel and power consumption of the screw compressor drive.

8. (canceled)

9. Method according to claim 2, wherein the calculating energy efficiency comprises
selecting multiple of rotational speeds,
calculating at least a second order polynomial fitting curves for pressure ratio and energy efficiency for selected rotational speeds,
selecting multiple of pressure ratios,
calculating at least a second order polynomial fitting curves for rotational speed and energy efficiency for selected pressure ratios, and
for each of the selected pressure ratios, determining a rotational speed having the best energy efficiency from the calculated polynomial fitting curves for rotational speed and energy efficiency.

10. Method according to claim 9, wherein after determining the rotational speed having the best energy efficiency, the rotational speed used in control of the frequency converter is selected based on the pressure ratio.

11. Method according to claim 2, wherein the power consumption of the screw compressor drive is estimated based on output power of the frequency converter and internal losses of the frequency converter.

12. Method according to claim 3, wherein the power consumption of the screw compressor drive is estimated based on output power of the frequency converter and internal losses of the frequency converter.

13. Method according to claim 4, wherein the power consumption of the screw compressor drive is estimated based on output power of the frequency converter and internal losses of the frequency converter.

14. Method according to claim 2, wherein the internal losses of the frequency converter are calculated on the basis of the torque of the motor, the nominal torque of the motor, output frequency of the frequency converter, nominal output frequency of the frequency converter and the losses of the frequency converter in a nominal operating point.

15. Method according to claim 3, wherein the internal losses of the frequency converter are calculated on the basis of the torque of the motor, the nominal torque of the motor, output frequency of the frequency converter, nominal output frequency of the frequency converter and the losses of the frequency converter in a nominal operating point.

16. Method according to claim 4, wherein the internal losses of the frequency converter are calculated on the basis of the torque of the motor, the nominal torque of the motor, output frequency of the frequency converter, nominal output frequency of the frequency converter and the losses of the frequency converter in a nominal operating point.

17. Method according to claim 5, wherein the internal losses of the frequency converter are calculated on the basis of the torque of the motor, the nominal torque of the motor, output frequency of the frequency converter, nominal output frequency of the frequency converter and the losses of the frequency converter in a nominal operating point.

18. A tangible, non-transitory, computer readable medium configured to store instructions executable by a processor operably coupled with a screw compressor driven with a frequency converter, wherein the instructions comprise:
pressurising a pressure vessel of the screw compressor with a variable rotational speed of the screw compressor, the rotational speed of the screw compressor having a speed profile in which the rotational speed is changed stepwise such that between stepwise changes the rotational speed of the screw compressor is kept substantially constant for a time period,
repeating the speed profile until the pressure of the pressure vessel reaches a set pressure value,
determining pressure of the pressure vessel, power consumption of the screw compressor drive and mass flow rate during the pressurising when the rotational speed of the screw compressor is kept substantially constant,
calculating energy efficiency of the screw compressor drive as a function of pressure of the pressure vessel and rotational speed of the screw compressor on the on the basis of the determined pressure of the pressure vessel and power consumption of the screw compressor drive.
